(19) United States
(12) Patent Application Publication
(10) Pub. No.: US 2026/0228879 A1
(43) Pub. Date: Aug. 6, 2026

(54) MACHINE VISION-BASED SHOWERHEAD INSPECTION

(71) Applicant: Lam Research Corporation, Fremont, CA (US)

(72) Inventors: Debotosh PODDAR, Durgapur (IN); Vineeth PARASHIVAMURTHY, Bangalore (IN); Karthik Adappa SATHISH, Bangalore (IN)

(21) Appl. No.: 19/151,400

(22) PCT Filed: Feb. 29, 2024
(86) PCT No.: PCT/US2024/017912

§ 371 Date: Jul. 28, 2025

Related U.S. Application Data
(60) Provisional application No. 63/488,735, filed on Mar. 6, 2023.

(51) Int. Cl. G06T 7/00; G06T 3/4046

(52) U.S. Cl. CPC G06T 7/0006; G06T 3/4046; G06T 2207/20084; G06T 2207/30164

(57) ABSTRACT

Examples are disclosed related to machine-vision based showerhead inspection systems and methods. One example provides a computing system for a machine vision-based inspection of a showerhead, the computing system comprising a processor and memory. The processor is configured to execute a program using portions of the memory to receive image data of the showerhead, identify a feature of interest in the image data of the showerhead, generate a cropped image based on the identified feature of interest using the image data of the showerhead, generate an upscaled image by upscaling the cropped image, and perform one or more measurement on the upscaled image.

### BACKGROUND

Process chambers are used to perform various semiconductor processes upon substrates such as silicon (Si) wafers. Example processes include deposition and etching processes. In such processes, a showerhead component is utilized for delivering process gas(es) and/or radiofrequency (RF) power into the chamber. The showerhead typically includes a large number of holes designed for the uniform delivery of the process gas(es). Depending on the application, the dimensions of these holes can be on the order of a few hundred micrometers. As semiconductor processes usually involve manipulating materials on a small scale, the precise manufacturing of these holes and their maintenance between processes can greatly affect the yield of such processes.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed related to machine-vision based showerhead inspection systems and methods. One example provides a computing system for a machine vision-based inspection of a showerhead, the computing system comprising a processor and memory. The processor is configured to execute a program using portions of the memory to receive image data of the showerhead, identify a feature of interest in the image data of the showerhead, generate a cropped image based on the identified feature of interest using the image data of the showerhead, generate an upscaled image by upscaling the cropped image, and perform one or more measurements on the upscaled images.

In some such examples, the showerhead additionally or alternatively comprises a faceplate and a backplate bonded together.

In some such examples, generating the cropped image comprises generating a plurality of cropped images, generating the upscaled image comprises generating a plurality of upscaled images by upscaling the plurality of cropped images, and performing the one or more measurements on the upscaled image comprises performing the one or more measurements on each upscaled image of the plurality of upscaled images.

In some such examples, the plurality of upscaled images is additionally or alternatively generated using a generative adversarial network.

In some such examples, the image data additionally or alternatively comprises a plurality of initial images, wherein each initial image includes a different portion of the showerhead.

In some such examples, the feature of interest additionally or alternatively comprises a showerhead hole.

In some such examples, the measurements additionally or alternatively comprise roundness measurements that include a maximum inscribed circle and a minimum circumscribed circle.

In some such examples, the processor is further configured to additionally or alternatively provide inspection results based on the performed measurements, wherein the inspection results describe a detected burr in the showerhead hole.

In some such examples, the feature of interest additionally or alternatively comprises a chamfer of a showerhead hole.

In some such examples, the plurality of cropped images additionally or alternatively includes images of a majority of showerhead holes of the showerhead.

Another example provides a method for machine vision-based inspection of a showerhead. The method comprises receiving image data of the showerhead, identifying a feature of interest in the image data of the showerhead, generating a plurality of cropped images based on the identified feature of interest using the image data of the showerhead, generating a plurality of upscaled images by upscaling the plurality of cropped images, and performing measurements on the plurality of upscaled images.

In some such examples, the showerhead additionally or alternatively comprises a faceplate and a backplate bonded together.

In some such examples, the image data is additionally or alternatively received from a remote device.

In some such examples, the plurality of upscaled images is additionally or alternatively generated using a generative adversarial network.

In some such examples, the method additionally or alternatively further comprises generating inspection results based on the performed measurements, wherein the inspection results describe a detected burr in a showerhead hole and transmitting the inspection results to a remote device.

Another example provides showerhead inspection system for a machine vision-based inspection of a showerhead, the showerhead inspection system comprising a camera system comprising a camera, a front lighting system, and a stage for seating the showerhead. The showerhead inspection system further comprises a computing system and a controller configured to control the camera system to acquire image data of the showerhead. The controller is further configured to control the computing system to receive the image data of the showerhead from the camera system, identify a feature of interest in the image data of the showerhead, generate a plurality of cropped images based on the identified feature of interest using the image data of the showerhead, generate a plurality of upscaled images by upscaling the plurality of cropped images, and perform measurements on the plurality of upscaled images.

In some such examples, the showerhead additionally or alternatively comprises a faceplate and a backplate bonded together.

In some such examples, the camera system additionally or alternatively further comprises a telecentric lens.

In some such examples, the plurality of upscaled images is additionally or alternatively generated using a generative adversarial network.

In some such examples, the controller is additionally or alternatively further configured to control the computing system to generate inspection results based on the performed measurements, wherein the inspection results describe a detected burr in a showerhead hole.

### BRIEF DESCRIPTION OF THE DRAWINGS

FIG. 1 shows a schematic view of an example computing system for the inspection of showerheads.

FIG. 2 shows an example imaging system for the inspection of showerheads.

FIGS. 3A and 3B show the transformations and analyses of image data from an example showerhead inspection process.

FIG. 4 shows an example showerhead inspection model.

FIG. 5 shows a flow diagram of an example method for inspecting showerheads.

FIG. 6 schematically shows a non-limiting embodiment of a computing system that can enact one or more of the methods and processes described above.

### DETAILED DESCRIPTION

The term “atomic layer deposition” (ALD) generally represents a process in which a film is formed on a substrate in one or more individual layers by sequentially adsorbing a precursor conformally to the substrate and reacting the adsorbed precursor to form a film layer. Examples of ALD processes comprise plasma-enhanced ALD (PEALD), remote plasma-enhanced ALD (RPEALD) and thermal ALD (TALD).

The terms “back light” and “back lighting” generally represent a process of illuminating a camera subject from the back, where the camera subject is between the light source and the camera.

The term “burr” generally represents a rough edge or area present on a surface.

The term “chamfer” generally represents a transitional edge between two surfaces. For example, a chamfer of a showerhead hole generally represents a bezel connecting the inner surface of a showerhead hole and the surface of a showerhead faceplate.

The term “chemical vapor deposition” (CVD) generally represents a process in which a solid phase film is formed on a substrate by directing a continuous flow of one or more precursor gases over the substrate surface under conditions configured to cause the chemical conversion of the precursor gases to the solid phase film.

The term “contour” generally represents an outline of a curved or irregular shape.

The terms “crop” and “cropping” generally represent the removal of unwanted portions from a content media.

The term “deposition” generally represents the formation of a film of a material on a substrate.

The term “etch” and variants thereof generally represent removal of material from a substrate.

The terms “front light” and “front lighting” generally represent a process of illuminating a camera subject from the front, where the light source directs light onto a same side of the camera subject as the camera.

The term “generative adversarial network” generally represents a class of machine learning architecture that utilize a generative model and a discriminator model to generate new data. An example generative adversarial network includes a super-resolution generative adversarial network (SRGAN) for upscaling input images and videos.

The term “least-squares circle” (LSC) generally represents a circle that separates a contour such that the sum of the total areas inside and outside the circle is in equal amounts.

The term “machine learning model” generally represents a computer program configured to recognize patterns in data and/or make predictions without being explicitly programmed to do so.

The term “maximum inscribed circle” (MIC) generally represents the largest circle that can be inscribed inside a contour.

The term “minimum circumscribed circle” (MCC) generally represents the smallest circle which encloses a contour.

The term “minimum zone circle” (MZC) generally represents an area between an MIC and an MCC.

The term “pedestal” generally represents a structure configured to hold a substrate in a processing chamber.

The term “processing chamber” generally represents an enclosure in which chemical and/or physical processes are performed on substrates. Example chemical and/or physical processes include ALD, CVD, and reactive ion etching processes.

The term “processing gas” generally represents a gas-phase chemical used during a process performed in a processing chamber.

The term “reactive ion etching” (RIE) generally represents an etching process in which a chemically reactive plasma is used to remove material from a substrate.

The term “showerhead” generally represents a processing gas outlet comprising a plurality of holes distributed across an area. A showerhead can comprise a faceplate configured to face toward a pedestal in a processing chamber. A showerhead also can comprise a backplate configured to face away from a pedestal in a processing chamber.

The term “showerhead hole” generally represents openings in a showerhead used to deliver processing gases.

The term “showerhead pedestal” generally represents a pedestal comprising one or more processing gas outlets configured to expose a substrate surface facing the pedestal to a processing gas. A showerhead pedestal can be used to perform a CVD process on a substrate backside.

The terms “upscale” and “upscaling” generally represent converting a content media into a higher resolution content media. Example content media includes audio data, image data, and video data.

The manufacturing and maintenance of showerheads for use in process chambers includes ensuring that the showerheads meet specifications. One aspect includes confirming that holes through which process gases are delivered do not deviate from their specifications. Deviations from their specifications can affect performance of the showerheads and lower yield of the processes in which the showerheads are implemented. Examples of such processes include various CVD, ALD, and RIE processes. Deviations can occur in a showerhead at various points in the showerhead's lifetime, including during manufacturing, assembly, and operation. For example, different manufacturers with different tooling and machines can produce showerheads having slight variations among each other. During the assembly/bonding process, showerhead holes can become distorted. During exposure to an etching process, such as during showerhead cleaning/maintenance, the showerhead holes can become too large. The ability to discern these variations can help with troubleshooting and determining corrective measures.

Another issue includes defects in the showerheads that can affect their performance. Examples of these defects include showerhead holes containing burrs or blockages. Such defects can occur within the showerhead holes or on the chamfers of the showerhead holes. Another example includes cracks in the showerhead. Inspection of the showerheads to locate these defects and the deviations described above can be difficult and costly in both time and resources. This is because a single showerhead can include thousands of holes with diameters on the micro-scale. As such, quality control methods generally include sample inspections where only a portion of showerheads and/or a subset of holes are inspected to infer quality of the entire batch.

Several different methods for the inspection of showerheads exist, including both destructive and non-destructive methods. Non-destructive inspection methods can involve the use of tactile or optical coordinate-measuring machines (CMMs). Tactile CMM is time intensive and, as such. As such, is difficult to perform tactile CMM for every hole of every showerhead in a cost-efficient manner. Optical CMM utilizes back lighting technology and therefore is incompatible with assembled, bonded showerheads. The inability to perform a final inspection after assembly of the showerhead prevents confirmation that the holes did not distort or deviate during the bonding process. Generally, measurements of bonded showerheads are taken by destructively cutting open the showerhead for inspection. Such methods may be used to provide sample data points to infer quality of a given batch of showerheads. However, the confidence levels of such quality assurance methods can be unsatisfactory for general use cases given the costs associated with implementing a flawed showerhead.

In view of the observations above, examples that relate to machine vision-based showerhead inspection are provided. In some aspects, the inspection model is implemented using machine vision techniques in combination with machine learning to employ an inspection process capable of inspecting every hole on a showerhead for defects. The model can be implemented as an inline automatic optical inspection system using the aforementioned techniques. Such an inspection system can provide a high-speed and efficient process for the full inspection of bonded showerheads in a non-destructive manner. In some implementations, full inspection of a showerhead can be performed within minutes compared to previous methods, which can take hours. The disclosed examples can provide a more consistent quality control process across a batch of showerheads and can provide for a more accurate inspection than may be possible using manual methods. The disclosed examples can also lead to lower yield loss for processes in which the showerheads are to be implemented.

The inspection model can be applied to inspect every hole of a showerhead while remaining efficient in terms of speed and resources. Compared to previous methods, different types of analyses can be performed in a more efficient manner. The inspection model can be applied to determine the presence of various defects, such as whether holes are too large after use in an etching process, whether holes are blocked, whether the showerhead contain cracks, etc. Such a model enables an operator to make certain assessments that would otherwise be difficult to make with previous sampling methods. For example, an efficient method of inspecting bonded showerheads enables the operator to quickly compare showerheads to determine the one most suitable for a given application, such as choosing the showerhead with the least number of defects for more critical applications. The ability to quickly inspect showerheads can also prevent early retirement of functional showerheads. This can reduce the lifetime costs of implementing showerheads. Another advantage of the inspection model includes the ability to inspect a showerhead faceplate for defects and flaws before the assembly and bonding of the faceplate and backplate. This allows the operator to avoid wasting time and resources in bonding defective showerhead parts.

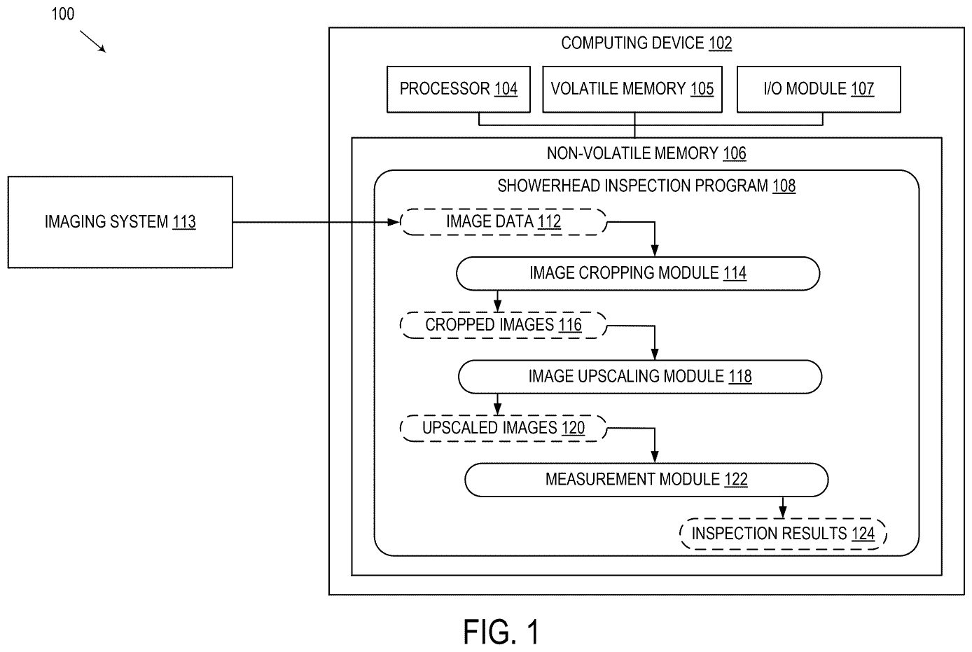

Referring now to FIG. 1, a schematic view of an example computing system 100 for the inspection of showerheads is illustrated. Although the descriptions herein describe an inspection process for a showerhead, it will be understood that such processes are applicable to similar components. Examples include unbonded showerhead faceplates and showerhead pedestals. The computing system 100 includes a computing device 102 that further includes a processor 104 (e.g., one or more central processing units, or “CPUs”), volatile memory 105, non-volatile memory 106, and an input/output (I/O) module 107. The different components are operatively coupled to one another. The non-volatile memory 106 stores a showerhead inspection program 108, which contains instructions for the various software modules described herein for execution by the processor 104.

Upon execution by the processor 104, the instructions stored in the showerhead inspection program 108 cause the processor 104 to initialize the showerhead inspection process. The showerhead inspect process includes retrieving image data 112 from an imaging system 113. The image data 112 can include one or more images of a showerhead. In some implementations, the image data 112 includes a single image of an entire showerhead. In other implementations, the image data 112 includes a plurality of images, each corresponding to a different portion of a showerhead.

The type of imaging system 113 from which the image data 112 is retrieved can depend on the application. In some implementations, the imaging system 113 is a remote camera device. For example, a cloud-based inspection system can be implemented where image data taken at the facility containing the showerhead is transmitted to a remote system (e.g., computing system 100) that provides inspection results in response. In other implementations, the imaging system 113 is locally connected to the computing system 100 as part of an inline inspection system. The imaging system 113 can be implemented using various types of cameras, including but not limited to charged-coupled device (CCD) cameras. In some implementations, the imaging system 113 is a handheld or otherwise mobile camera. Examples include smart phone cameras and wearable device cameras, such as cameras incorporated into a head-mounted device.

The showerhead inspection program 108 includes an image cropping module 114 that receives the retrieved image data 112 as input and generates a plurality of cropped images 116 corresponding to features of interest on the showerhead. For example, the image cropping module 114 can receive image data 112 that includes an initial image of a showerhead (or a portion of the showerhead) and generate cropped images 116 of individual holes of the showerhead. The image cropping process can be performed using various machine vision techniques. Example techniques include feature detection/extraction algorithms for isolating the features of interest. In some implementations, the image cropping module 114 applies an edge detection algorithm to the image data 112 to identify holes in the showerhead. In some implementations, the image cropping module 114 applies a circle Hough transform (CHT) algorithm. The identified holes can then be cropped to generate the plurality of cropped images 116. Such techniques can also be applied to identify other features of interests, including but not limited to chamfers of showerhead holes. As can readily be appreciated, different feature extraction techniques can be applied depending on the features of interest. For example, edge detection algorithms can be applied to identify cracks on the surfaces of a showerhead.

Additionally or alternatively, a machine learning model can be applied to identify the features of interest. As an example, a machine learning model such as a feedforward neural network (e.g. a convolutional neural network) can be used to identify features of interests, such showerhead holes and chamfers of showerhead holes. Such a neural network can be trained using labeled training data comprising images of showerheads with features of interest, as well as showerheads without such features. Additionally, the model can be trained to identify multiple different features of interest. Any suitable training methods can be used to train such a neural network. As one example, a stochastic gradient descent algorithm with back propagation can be used to train a feedforward neural network. Any suitable loss function can be optimized in such a process. Examples include a mean squared error and mean absolute error. Other types of machine learning models can be used. For example, unsupervised machine learning models can be used to identify the features of interest. An example training method for such machine learning models includes using unlabeled training data comprising images of showerheads, different features of interest of showerheads, and/or different defects of interest of showerheads. The algorithm employed by the unsupervised machine learning model attempts to identify patterns within the unlabeled training data to categorize the data within different groupings (e.g., different features of interest).

The showerhead inspection program 108 further includes an image upscaling module 118 for generating a plurality of upscaled images 120 using the plurality of cropped images 116. After the cropping process, the plurality of cropped images 116 is of relatively low-resolution. For example, cropping thousands of individual holes from one or more initial images of a showerhead can generate cropped images that are much smaller in resolution than the initial image(s). In some implementations, the cropped images have resolutions smaller than or equal to 128 by 128 pixels. In further implementations, the cropped images have resolutions of 32 by 32 pixels. To discern information from images of such quality, the upscaling module 118 can be implemented to generate images with higher resolutions and finer details. The upscaled images can be of any suitable resolution. In some implementations, the upscaled images have a resolution of at least 128 by 128 pixels. Different types of upscaling techniques can be implemented. In some implementations, the upscaling module 118 utilizes a machine learning model to perform the upscaling. For example, a generative adversarial network, such as a super-resolution generative adversarial network, can be implemented to upscale the plurality of cropped images 116. Other upscaling techniques, such as an interpolation-based upscaling technique, can also be applied.

The showerhead inspection program 108 further includes a measurement module 122 for determining various measurement fittings using the plurality of upscaled images 120. The measurements can be used to determine whether the features of interest satisfy a predetermined inspection criterion. In some implementations, measurements are performed for determining various dimensions, including but not limited to the area, the roundness, the center, and the aperture of showerhead holes. Based on these measurements, other details such as defects and errors can be determined. For example, the measurements can be used to identify surface cracks, multi-holes, missing holes, holes with roundness error, holes with position errors, and holes with defects such as burrs and blockages. The measurements can also be used to show the distribution of offset between the desired hole and a manufactured hole.

The measurement module 122 can perform the various measurements by applying fitting algorithms on each upscaled image 120. Different fitting algorithms can be applied depending on the features of interest. In applications for inspecting holes of a showerhead, the measurement module 122 can be implemented to perform a plurality of roundness measurements on each upscaled image 120 to determine if the holes deviate from a predetermined specification. The roundness measurements can then be used to determine the existence of certain defects such as burrs and blockages. An example technique for performing such measurements includes using an edge detection algorithm, such as a Canny edge detector, to identify a contour of the hole. From the contour of the hole, various roundness measurements can be defined. Roundness measurements can include but are not limited to maximum inscribed circle, minimum circumscribed circle, minimum zone circle, and least-squares circle. As can readily be appreciated, different measurements can be performed depending on the feature of interest and/or the defect to be identified. For example, edge detection algorithms can be applied to generate edge contours, which can be used to identify cracks on the surfaces of a showerhead. In such implementations, circular contours corresponding to the edges of the showerhead and the showerhead holes can be filtered out. Remaining contours can be inspected to determine defects (e.g., cracks) on the surface of the showerhead.

The measurement module 122 outputs inspection results 124 based on the determined measurements. In a cloud-based inspection system, the inspection results 124 can be transmitted to the appropriate system, such as the system from which the initial image data 112 is received. The inspection results 124 can include data describing various details of a given feature of interest, such as the diameter of a hole, manufacturing offset, and the defects discovered. In some implementations, the inspection results 124 include data describing whether the features of interest in the plurality of upscaled images 120 satisfy a predetermined inspection criterion. For example, the inspection results 124 can include data indicating whether a given hole in the inspected showerhead satisfies a roundness criterion. An example criterion can include whether the minimum circumscribed circle of a hole is within a predetermined tolerance. Another example includes whether the minimum zone circle of a hole is below a predetermined threshold.

In some implementations, the inspection results 124 include data describing the type of defect(s) discovered in a given showerhead hole. Such information can be derived from the measurements. For example, a hole having similar minimum circumscribed circle and least-squares circle measurements but a relatively smaller maximum inscribed circle can indicate a localized defect, which can indicate the presence of a burr. Relatively large differences in minimum circumscribed circle and maximum inscribed circle measurements can indicate a blockage or an irregular-shaped hole.

The inspection results 124 can also be determined using a machine learning model. Different machine learning models including supervised and unsupervised models can be implemented. For example, a machine learning model such as a feedforward neural network (e.g. a convolutional neural network) can be used to identify the presence of defects such as cracks in a showerhead. In some implementations, an artificial neural network is employed to utilize the measurements to predict the presence of a defect and/or the type of defect. Examples of machine learning models are described in more detail above.

The example computing system and various software modules described above with respect to FIG. 1 provide a pipeline in which image data of showerheads are transformed and analyzed to provide inspection results. Different system configurations can be implemented depending on the application. For example, in a local showerhead inspection system, a controller can be implemented to control the imaging system 113 to acquire the image data 112 of the showerhead. The controller can also be configured to control the computing device 102 to perform the various steps associated with the showerhead inspection program 108 and its software modules.

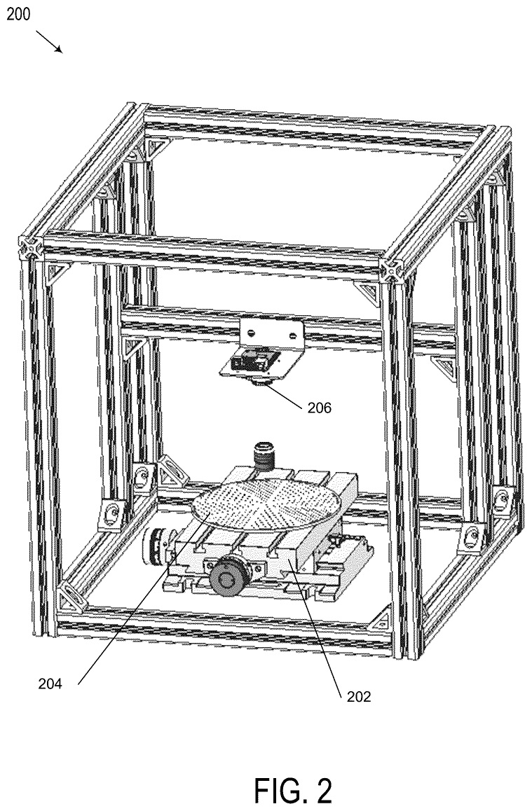

The imaging system 113 described above can be implemented using various types of camera systems and setups. FIG. 2 shows an example imaging system 200 for the inspection of showerheads. The imaging system 200 includes a stage 202 for seating showerheads and associated components. In the depicted example, the stage 202 seats a showerhead 204. As shown, the faceplate of the showerhead 204 is facing the camera 206—i.e., the showerhead holes are facing the camera 206. The stage 202 is a movable stage that can position the showerhead 204 in three dimensions relative to a camera 206 and a light source. In some implementations, the stage 202 is fixed in place. Additionally or alternatively, the camera 206 can be mounted on a three-axis gantry system. In such systems, the stage 202 and/or camera 206 can be positioned to perform a raster scan of the showerhead 204 and acquire a plurality of segmented images. In some implementations, the raster scan is performed automatically. The imaging system 200 can be configured to utilize front lighting. Although front lighting can result in lower quality images compared to back lighting, such systems enable the non-destructive optical inspection of holes on a bonded showerhead. Various types of cameras, such as visible light cameras, can be utilized. In some implementations, camera 206 is a CCD camera. In some implementations, the camera 206 can include a telecentric lens.

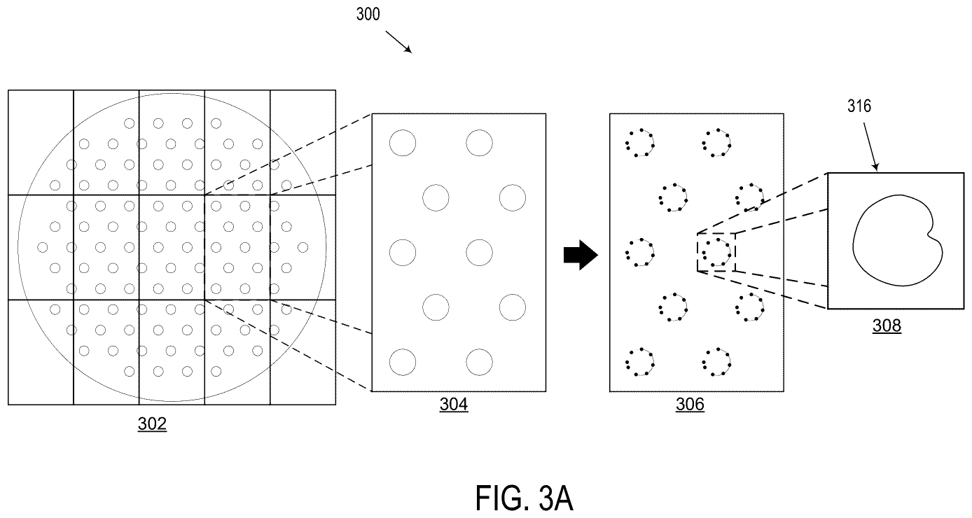

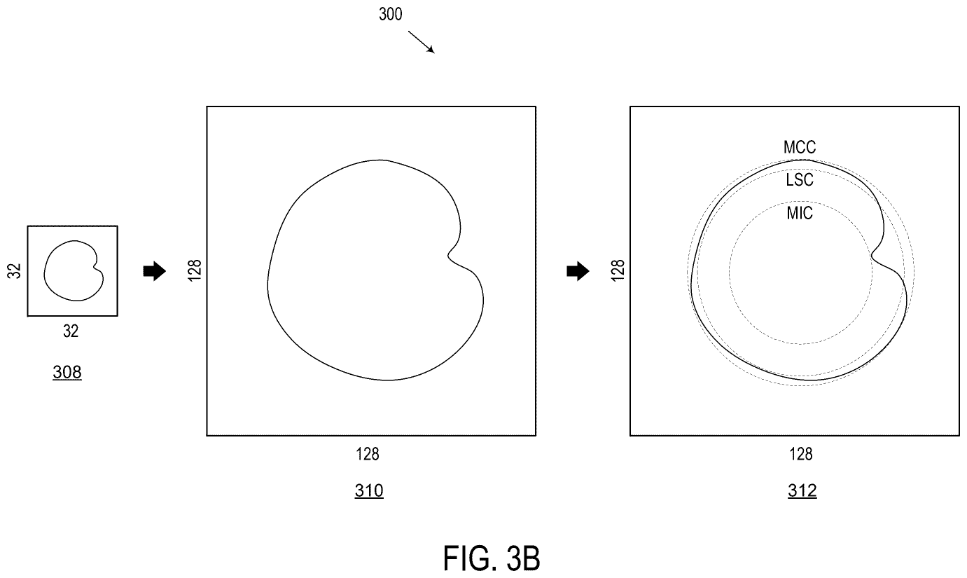

Referring now to FIGS. 3A and 3B, the transformations and analyses of image data from an example showerhead inspection process 300 are illustrated. The depicted images in FIGS. 3A and 3B are not shown to scale and are illustrated as such for convenience. For example, a showerhead can include hundreds or thousands of holes with dimensions much smaller than that shown relative to the overall showerhead size.

FIG. 3A shows a feature extraction process in the image data pipeline. Extraction of features of interest lowers the amount of image data to be analyzed in upcoming steps. This can expedite the inspection process 300. In the example inspection process 300, the features of interest are showerhead holes. In some implementations, the features of interest are chamfers of showerhead holes.

At step 302, the process includes dividing up the showerhead that is to be inspected into a plurality of segments. This consequently also divides the showerhead holes into different portions. Although FIG. 3A shows the showerhead divided up into fifteen segments, the process can be implemented with any number of segments. In some cases, the number of segments depends on the type and quality of camera utilized.

At step 304, an imaging system, such as the one illustrated in FIG. 2 for example, is utilized to acquire a plurality of initial images from the showerhead. The plurality of initial images corresponds to the plurality of segments. Step 304 shows an example initial image.

At step 306, features of interest are identified in the initial images. In the example inspection process 300, the features of interest are the showerhead holes. Showerhead holes in the initial images can be identified using various machine vision techniques. For example, a circle Hough transform can be applied to detect the locations of the showerhead holes. Additionally or alternatively, machine learning models can be applied to identify features of interest. Examples of machine vision techniques and machine learning models are described in more detail above.

At step 308, the detected showerhead holes are cropped out of the initial images to generate a plurality of cropped images. Step 308 shows an example cropped image. Each of the cropped images has a lower resolution than the initial images. Given the diameters of showerhead holes in general, the cropped images can have a much smaller resolution than the initial images. In some implementations, the cropped images have a resolution of at least 32 by 32 pixels. As can readily be appreciated, the resolution of the cropped images depicting the features of interest can be of any resolution, which can be dependent on the imaging system utilized and the resolution of the images acquired from such image system. For example, in some implementations, the initial images have a resolution of 4056 by 3040 pixels while the cropped images have a resolution of 32 by 32 pixels.

Referring now to FIG. 3B, steps for upscaling and performing measurements on the cropped images are illustrated. At step 310, the plurality of cropped images is upscaled to generate a plurality of upscaled images. The upscaling process can be performed using various methods. In some implementations, the cropped images are upscaled using a super-resolution generative adversarial network. SRGANs can be implemented to upscale a low-resolution image into a high-resolution image. In addition to upscaling the images, the SRGAN can recover finer details and textures. In some implementations, the SRGAN implemented can achieve an upscaling factor of four. SRGANs can be implemented in various ways. For example, the SRGAN implemented can be a model trained using high-resolution images of showerhead holes as training data. The training process can include upscaling a low-resolution image of a showerhead hole and comparing the result to a corresponding high-resolution image of the showerhead hole.

In the example inspection process 300, the SRGAN upscales each cropped image from a resolution of 32 by 32 pixels to a resolution of 128 by 128 pixels. Different resolutions may be implemented depending on the application. As can readily be appreciated, other upscaling techniques can also be utilized. In some implementations, an interpolation-based upscaling technique is utilized. In some implementations, a convolutional neural network (CNN) is utilized to perform the upscaling. In such cases, the resulting upscaled images may lack finer details compared to the use of SRGANs.

At step 312, a number of measurements is performed on the upscaled images. In the example inspection process 300, machine vision techniques are utilized to determine various roundness measurements, which can provide details such as dimensions and the presence of defects for a given showerhead hole. The roundness measurements performed can include MIC, MCC, MZC, and LSC measurements. Step 312 illustrates MCC, LSC, and MIC measurements on an example upscaled image. Based on these measurements, the inspection process 300 can output inspection results describing details about the showerhead hole. Additionally or alternatively, a machine learning model can be applied to output the inspection results based on the upscaled images and/or performed measurements.

Although the example inspection process 300 illustrates a pipeline for the inspection of showerhead holes, such a model can be similarly configured for the general inspection of showerheads and related components. For example, the inspection process 300 can similarly be applied for the detection of cracks in showerheads and showerhead pedestals.

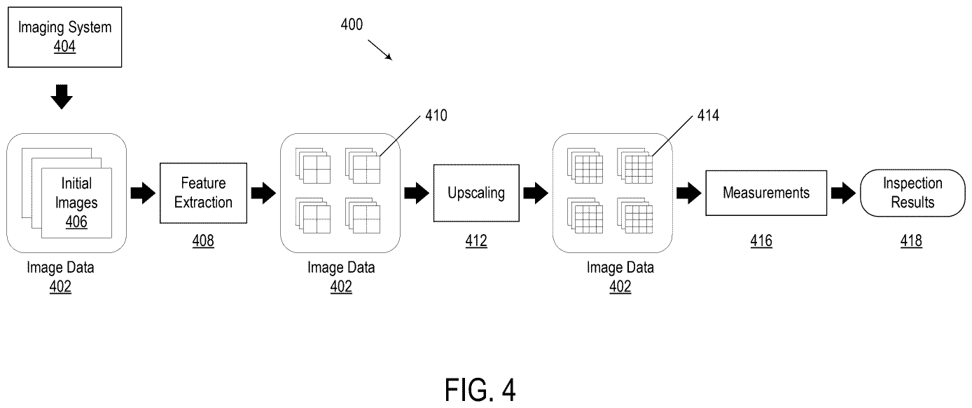

FIG. 4 shows a generalized showerhead inspection model 400 schematically illustrating the transformation and analysis of image data 402 of showerheads and related components. The showerhead inspection model 400 starts with an imaging system 404 that provides the image data 402. The imaging system 404 can be implemented using various camera systems and configurations. In some implementations, the imaging system 404 is an inline image acquisition machine, which can be implemented as part of a maintenance and/or manufacturing system. As can readily be appreciated, the type of imaging system 404 utilized can vary widely and can depend on the application. Higher resolution cameras can result in better error detection while lower resolution cameras can be inexpensive to implement.

The image data 402 provided by the imaging system 404 can be of various formats. In the depicted example, the image data 402 includes a plurality of initial images 406 of a showerhead. The plurality of initial images 406 can be segmented images of the showerhead, each corresponding to a different portion of the showerhead. The term “different portion” generally refers to any geometrical differences between two portions. As such, different portions can be overlapping or nonoverlapping in various examples. In other implementations, the image data 402 includes an image depicting the entire showerhead, which can shorten the image acquisition time at the cost of image resolution (given the same imaging system). Lower initial image resolution can result in less accurate error detection depending on the application. For example, in applications for the inspection of showerhead holes, low image resolution may be insufficient as showerhead holes generally have diameters on the order of a few hundred micrometers. In such cases, acquiring multiple segmented images instead of a single whole image can be worth the additional time.

The showerhead inspection model 400 includes a feature extraction process 408 for cropping the initial images 406 such that the remaining portions correspond to features of interest. For example, showerhead holes and/or chamfers of showerhead holes can be cropped out of an initial image of a showerhead. As showerhead holes can be many orders of magnitude smaller than the showerhead itself, the feature extraction process 408 greatly reduces the amount of image data to be analyzed. The feature extraction process 408 includes, for each initial image 406, detecting the features of interest. Various methods can be utilized for identifying features of interest, including but not limited to edge detection techniques. For example, a circle Hough transform can be applied for detecting circles in imperfect images for the identification of showerhead holes. Once identified, the features of interest can be cropped to generate a plurality of cropped images 410. In some implementations, the initial images 406 are cropped to contain the identified features of interest at a predetermined image resolution. For example, the initial images 406 can be cropped to generate cropped images 410 having a resolution of 32 by 32 pixels. As can readily be appreciated, the initial images 406 can be cropped to have any other resolution.

The cropping process generates cropped images 410 that are lower in resolution compared to the initial images 406. Inspecting the features of low-resolution images can be difficult and unlikely to yield any meaningful results. As such, the model 400 includes an upscaling process 412 for converting the cropped images 410 into higher resolution upscaled images 414. The upscaling process 412 can be performed using a super resolution generative adversarial network. SRGANs can be implemented to recover finer textures from the cropped images, enabling analyses to be made in a more meaningful manner. Other upscaling techniques can also be utilized, including but not limited to other machine learning techniques. For example, in some implementations, the upscaling process employs an interpolation-based upscaling technique. In other implementations, the upscaling process employs a CNN.

With the increase in resolution and finer textures using the techniques described above, features present in the upscaled images 414 can be more easily detected. The showerhead inspection model 400 includes a measurement fitting process 416 that applies various algorithms to provide measurements used to evaluate the characteristics of the features of interest. For example, roundness measurements can be used to inspect showerhead holes and/or chamfers of showerhead holes for defects such as irregular shapes, burrs, blockage, etc. Examples of roundness measurements include MIC, MCC, MZC, and LSC measurements.

The showerhead inspection model 400 outputs inspection result data 418 based on the measurement fittings. The inspection result data 418 can include various details about the features of the interest. For example, in applications for the inspection of showerhead holes, the inspection results can include information regarding characteristics of the showerhead holes such as dimensions and identified defects.

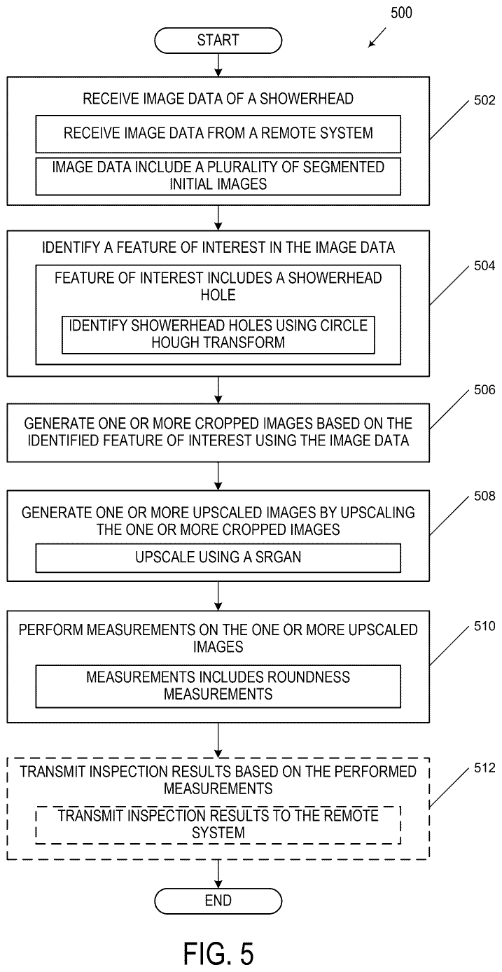

FIG. 5 shows a flow diagram of an example method 500 for inspecting showerheads and related components. Examples include showerheads comprising bonded faceplates and backplates, unbonded showerhead faceplates, and showerhead pedestals. Method 500 can be implemented using any suitable hardware. Examples include computing system 100 and computing device 102 as described above. Images may be captured by imaging system 113, imaging system 200, or any other suitable imaging system. At step 502, the method 500 includes receiving image data of a showerhead. The image data can be received from various sources. In some implementations, the image data is received from a remote device. In other implementations, the image data is received from a local device. For example, the image data can be received from an imaging system as part of an inline optical inspection system.

An imaging system (e.g., imaging system 113, imaging system 200) can be implemented in many ways. In some implementations, the imaging system is implemented as a front light imaging system. The imaging system can also include various components to facilitate the imaging of showerheads. For example, the imaging system can include a stage for seating a showerhead. In some implementations, the stage is a movable stage. The imaging system can include one or more cameras. In some implementations, the stage and/or camera can be repositioned to acquire images of different segments of the showerhead. For example, the camera can be mounted on a three-axis gantry system. Different types of cameras can be implemented. In some implementations, the imaging system includes a CCD camera. In some implementations, the imaging system includes a handheld camera.

The image data can include one or more images. In some implementations, the image data includes a single initial image of an entire showerhead. In other implementations, the image data includes a plurality of initial images, where each initial image corresponds to a different portion of the showerhead (e.g., step 304 illustrates an example initial image that correspond to a portion of a showerhead).

At step 504, the method 500 includes identifying a feature of interest in the image data (e.g., step 306). Showerheads include various features of interests, including but not limited to showerhead holes and chamfers of showerhead holes. Additionally or alternatively, the features of interest include cracks on the surface of the showerhead. The features of interest can be identified using various techniques. In some cases, the technique utilized can depend on the features of interest. In some implementations, a circle Hough transform algorithm is applied to identify showerhead holes. In some implementations, edge detection algorithms are implemented.

At step 506, the method 500 includes generating one or more cropped images based on the identified feature of interest. In some examples, a plurality of cropped images are generated. The plurality of cropped images can be generated by cropping the features of interest out of the initial image(s) (e.g., step 308). In some implementations, the plurality of cropped images includes images of a majority of showerhead holes of the showerhead. In further implementations, the plurality of cropped images includes images of every hole of the showerhead. In some implementations, the images are cropped to a predetermined resolution. The plurality of cropped images can be of any resolution. In some implementations, the cropped images have a resolution of less than 128 by 128 pixels. In further implementations, the cropped images have a resolution of 32 by 32 pixels.

At step 508, the method 500 includes generating one or more upscaled images by upscaling the one or more cropped images. In some examples, the method 500 includes generating a plurality of upscaled images by upscaling the plurality of cropped images (e.g., step 310). The cropped images can be upscaled using various techniques (e.g., upscaling process 412). In some implementations, an SRGAN or other GAN is implemented to upscale the plurality of cropped images. In addition to upscaling the resolution of the cropped images, the SRGAN can also recover finer details and textures in the images. Other machine learning models such as CNNs can also be implemented to perform the upscaling. In some implementations, each cropped image of the plurality of cropped images is upscaled using an interpolation-based technique. The upscaled images can be of any resolution. In some implementations, the upscaled cropped images have a resolution of at least 128 by 128 pixels. The resolution of the upscaled cropped images can depend on the technique utilized and the resolution of the plurality of cropped images. For example, an SRGAN capable of an upscaling factor of four can be implemented to upscale a cropped image having a resolution of 32 by 32 pixels to a resolution of 128 by 128 pixels. In other examples, a cropped image can be upscaled from any other suitable starting resolution than 32 by 32 pixels. Further, a cropped image can be upsampled to any other suitable resolution than 128 by 128 pixels.

At step 510, the method 500 includes performing measurements on the plurality of upscaled images. Different types of measurements can be performed depending on the features of interest (e.g., step 312 illustrates an example set of roundness measurements performed on an upscaled image). In some implementations, measurements are performed for determining various dimensions, including but not limited to the area, the roundness, the center, and the aperture of showerhead holes. Based on these measurements, other details such as defects and errors can be determined. For example, the measurements can be used to identify surface cracks, multi-holes, missing holes, holes with roundness error, holes with position errors, and holes with defects such as burrs and blockages. The measurements can also be used to show the distribution of offset between the desired hole and a manufactured hole.

The measurements can be performed by applying various machine vision-based algorithms on the upscaled images. For example, in some implementations, a Canny edge detector algorithm is applied to identify a contour of the showerhead hole. Various roundness measurements can be performed based on the identified contour. Roundness measurements can include but are not limited to maximum inscribed circle, minimum circumscribed circle, minimum zone circle, and least-squares circle.

At step 512, the method 500 optionally includes transmitting inspection results. Inspection results can be generated based on the various measurements performed on the upscaled images. The inspection results can include data describing various details of a given feature of interest, such as the diameter of a showerhead hole and any present defect. In some implementations, the inspection results include data describing whether the features of interest in the plurality of upscaled images satisfy a predetermined inspection criterion.

The inspection results can be transmitted to various devices. In some implementations, the inspection results are transmitted to a remote device. For example, in a cloud-based inspection system, image data is received from a remote inspection system. The image data is analyzed, and inspection results are transmitted to the remote inspection system. In other implementations, the inspection results are provided and transmitted to a local device.

The method 500 described in FIG. 5 provide a general framework in which a showerhead inspection system can be implemented. Some aspects are directed towards machine vision and machine learning techniques. Taking advantage of these techniques, a showerhead inspection system capable of inspecting every hole of a showerhead can be implemented in an efficient and high-speed manner. Such systems can be well-suited for implementation as an inline optical inspection system, leading to more consistent quality control and lower yield loss.

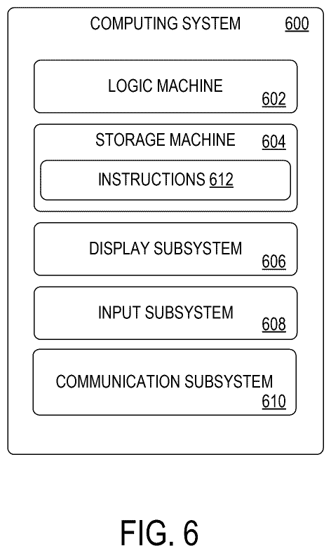

FIG. 6 schematically shows a non-limiting embodiment of a computing system 600 that can enact one or more of the methods and processes described above. Computing system 600 is shown in simplified form. Computing system 600 may take the form of one or more personal computers, workstations, computers integrated with substrate processing tools, and/or network accessible server computers.

Computing system 600 includes a logic machine 602 and a storage machine 604. Computing system 600 may optionally include a display subsystem 606, input subsystem 608, communication subsystem 610, and/or other components not shown in FIG. 6. The controller described above with respect to FIG. 1 is an example of computing system 600.

Logic machine 602 includes one or more physical devices configured to execute instructions. For example, the logic machine 602 may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine 602 may include one or more processors configured to execute software instructions. Additionally or alternatively, the logic machine 602 may include one or more hardware or firmware logic machines configured to execute hardware or firmware instructions. Processors of the logic machine 602 may be single-core or multi-core, and the instructions executed thereon may be configured for sequential, parallel, and/or distributed processing. Individual components of the logic machine 602 optionally may be distributed among two or more separate devices, which may be remotely located and/or configured for coordinated processing. Aspects of the logic machine 602 may be virtualized and executed by remotely accessible, networked computing devices configured in a cloud-computing configuration.

Storage machine 604 includes one or more physical devices configured to hold instructions 612 executable by the logic machine 602 to implement the methods and processes described herein. When such methods and processes are implemented, the state of storage machine 604 may be transformed—e.g., to hold different data.

Storage machine 604 may include removable and/or built-in devices. Storage machine 604 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 604 may include volatile, nonvolatile, dynamic, static, read/write, read-only, random-access, sequential-access, location-addressable, file-addressable, and/or content-addressable devices.

It will be appreciated that storage machine 604 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 602 and storage machine 604 may be integrated together into one or more hardware-logic components. Such hardware-logic components may include field-programmable gate arrays (FPGAs), program-and application-specific integrated circuits (PASIC/ASICs), program-and application-specific standard products (PSSP/ASSPs), system-on-a-chip (SOC), and complex programmable logic devices (CPLDs), for example.

When included, display subsystem 606 may be used to present a visual representation of data held by storage machine 604. This visual representation may take the form of a graphical user interface (GUI). As the herein described methods and processes change the data held by the storage machine, and thus transform the state of the storage machine, the state of display subsystem 606 may likewise be transformed to visually represent changes in the underlying data. Display subsystem 606 may include one or more display devices utilizing virtually any type of technology. Such display devices may be combined with logic machine 602 and/or storage machine 604 in a shared enclosure, or such display devices may be peripheral display devices.

When included, input subsystem 608 may comprise or interface with one or more user-input devices such as a keyboard, mouse, or touch screen. In some embodiments, the input subsystem 608 may comprise or interface with selected natural user input (NUI) componentry. Such componentry may be integrated or peripheral, and the transduction and/or processing of input actions may be handled on-or off-board. Example NUI componentry may include a microphone for speech and/or voice recognition, and an infrared, color, stereoscopic, and/or depth camera for machine vision and/or gesture recognition.

When included, communication subsystem 610 may be configured to communicatively couple computing system 600 with one or more other computing devices. Communication subsystem 610 may include wired and/or wireless communication devices compatible with one or more different communication protocols. As non-limiting examples, the communication subsystem 610 may be configured for communication via a wireless telephone network, or a wired or wireless local-or wide-area network. In some embodiments, the communication subsystem 610 may allow computing system 600 to send and/or receive messages to and/or from other devices via a network such as the Internet.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

The subject matter of the present disclosure includes all novel and non-obvious combinations and sub-combinations of the various processes, systems and configurations, and other features, functions, acts, and/or properties disclosed herein, as well as any and all equivalents thereof.

1. A computing system for a machine vision-based inspection of a showerhead, the computing system comprising:
a processor and memory, the processor configured to execute a program using portions of the memory to:
receive image data of the showerhead;
identify a feature of interest in the image data of the showerhead;
generate a cropped image based on the identified feature of interest using the image data of the showerhead;
generate an upscaled image by upscaling the cropped image; and
perform one or more measurements on the upscaled image.

2. The computing system of claim 1, wherein the showerhead comprises a faceplate and a backplate bonded together.

3. The computing system of claim 1, wherein generating the cropped image comprises generating a plurality of cropped images, wherein generating the upscaled image comprises generating a plurality of upscaled images by upscaling the plurality of cropped images, and wherein performing the one or more measurements on the upscaled image comprises performing the one or more measurements on each upscaled image of the plurality of upscaled images.

4. The computing system of claim 1, wherein the plurality of upscaled images is generated using a generative adversarial network.

5. The computing system of claim 1, wherein the image data comprises a plurality of initial images, wherein each initial image includes a different portion of the showerhead.

6. The computing system of claim 1, wherein the feature of interest comprises a showerhead hole.

7. The computing system of claim 6, wherein the measurements comprise roundness measurements that include a maximum inscribed circle and a minimum circumscribed circle.

8. The computing system of claim 6, wherein the processor is further configured to provide inspection results based on the performed measurements, wherein the inspection results describe a detected burr in the showerhead hole.

9. The computing system of claim 1, wherein the feature of interest comprises a chamfer of a showerhead hole.

10. The computing system of claim 3, wherein the plurality of cropped images includes images of a majority of showerhead holes of the showerhead.

11. A method for machine vision-based inspection of a showerhead, the method comprising:
receiving image data of the showerhead;
identifying a feature of interest in the image data of the showerhead;
generating a plurality of cropped images based on the identified feature of interest using the image data of the showerhead;
generating a plurality of upscaled images by upscaling the plurality of cropped images; and
performing measurements on the plurality of upscaled images.

12. The method of claim 11, wherein the showerhead comprises a faceplate and a backplate bonded together.

13. The method of claim 11, wherein the image data is received from a remote device.

14. The method of claim 11, wherein the plurality of upscaled images is generated using a generative adversarial network.

15. The method of claim 11, further comprising:
generating inspection results based on the performed measurements, wherein the inspection results describe a detected burr in a showerhead hole; and
transmitting the inspection results to a remote device.

16. A showerhead inspection system for a machine vision-based inspection of a showerhead, the showerhead inspection system comprising:
a camera system comprising:
a camera;
a front lighting system; and
a stage for seating the showerhead;
a computing system; and
a controller configured to:
control the camera system to acquire image data of the showerhead; and
control the computing system to:
receive the image data of the showerhead from the camera system;
identify a feature of interest in the image data of the showerhead;
generate a plurality of cropped images based on the identified feature of interest using the image data of the showerhead;
generate a plurality of upscaled images by upscaling the plurality of cropped images; and
perform measurements on the plurality of upscaled images.

17. The showerhead inspection system of claim 16, wherein the showerhead comprises a faceplate and a backplate bonded together.

18. The showerhead inspection system of claim 16, wherein the camera system further comprises a telecentric lens.

19. The showerhead inspection system of claim 16, wherein the plurality of upscaled images is generated using a generative adversarial network.

20. The showerhead inspection system of claim 16, wherein the controller is further configured to control the computing system to generate inspection results based on the performed measurements, wherein the inspection results describe a detected burr in a showerhead hole.
